(19) United States
(12) Patent Application Publication
(10) Pub. No.: US 2024/0006236 A1
(43) Pub. Date: Jan. 4, 2024

(54) PLASMA ENHANCED TUNGSTEN NUCLEATION FOR LOW RESISTIVITY

(71) Applicant: Applied Materials, Inc., Santa Clara, CA (US)

(72) Inventors: Tsung-Han YANG, San Jose, CA (US); Junyeong YUN, Santa Clara, CA (US); Rongjun WANG, Dublin, CA (US); Yi XU, San Jose, CA (US); Yu LEI, Belmont, CA (US); Wenting HOU, Sunnyvale, CA (US); Xianmin TANG, San Jose, CA (US)

(21) Appl. No.: 18/133,065

(22) Filed: Apr. 11, 2023

Related U.S. Application Data
(60) Provisional application No. 63/357,472, filed on Jun. 30, 2022.

(51) Int. Cl. H01L 21/768; H01J 37/32

(52) U.S. Cl. CPC H01L 21/76876; H01J 37/321; H01L 21/76843; H01L 21/76895; H01J 2237/338; H01J 37/32899

(57) ABSTRACT

A method of forming a structure on a substrate includes forming a tungsten nucleation layer within at least one feature. The method includes forming the nucleation layer via a cyclic vapor deposition process. The cyclic vapor deposition process includes forming a portion of the nucleation layer and then exposing the exposing the nucleation layer a chemical vapor transport (CVT) process to remove impurities from the portion of the nucleation layer. The CVT process may be performed at a temperature of 400 degrees Celsius or less and comprises forming a plasma from a processing gas comprising greater than or equal to 90% of hydrogen gas of a total flow of hydrogen gas and oxygen.

### CROSS-REFERENCE TO RELATED APPLICATIONS

This application claims the benefit of U.S. Provisional Patent Application Ser. No. 63/357,472, filed Jun. 30, 2022, which is incorporated by reference herein in its entirety.

### TECHNICAL FIELD

The present disclosure relates to a method and apparatus for forming thin-films. More particularly, the disclosure relates to a method and apparatus for metal-fill in semiconductor devices.

### BACKGROUND

The fabrication of microelectronic devices typically involves a complicated process sequence requiring hundreds of individual processes performed on semi-conductive, dielectric and conductive substrates. Examples of these processes include oxidation, diffusion, ion implantation, thin film deposition, cleaning, etching, lithography among other operations. Each operation is time consuming and expensive.

With ever-decreasing critical dimensions for the microelectronic devices, the design and fabrication for these devices on substrates becomes increasingly complex. Control of the critical dimensions and process uniformity becomes increasingly more significant. Complex multilayer stacks involve precise process monitoring of the critical dimensions for the thickness, roughness, stress, density, and potential defects. Multiple incremental processes in the process recipes for forming the devices ensure critical dimensions are maintained. However, each recipe process may utilize one or more process chambers that adds additional time for forming the devices in the processing systems and also provides additional opportunities for forming defects. Thus, each process adds to the overall fabrication cost for the completed microelectronic devices.

Additionally, as critical dimensions on these devices shrink, past fabrication techniques encounter new hurdles. For example, as a liner and/or nucleation layer is prepared to grow a metal gap-fill, the liner and/or nucleation layer may be still be present on the sides of the gap causing the fill material to close off the gap prior to completely filling resulting in seams in the fill material.

For at least the foregoing reasons, there is an ongoing need for improved fabrication methods to minimize cost while maintaining critical dimensions for microelectronic devices.

### SUMMARY

The present disclosure relates to a method and apparatus for forming thin-films. More particularly, the disclosure relates to a method and apparatus for metal-fill in semiconductor devices.

In one aspect, a method of filling a feature on a substrate is provided. The method includes forming a nucleation layer in at least one feature formed on a substrate by performing a nucleation layer deposition cycle. The nucleation layer deposition cycle includes exposing the at least one feature formed on a substrate to a tungsten-containing gas at a precursor flow rate, exposing the at least one opening of the substrate to one or more reducing agents at a reducing agent flow rate, wherein the tungsten-containing gas and the reducing agent form a portion of the nucleation layer within the at least one feature, exposing the portion of the nucleation layer to a chemical vapor transport (CVT) process to remove impurities from the portion of the nucleation layer. The method further includes repeating the nucleation layer deposition cycle until the nucleation layer achieves a desired thickness.

Implementations may include one or more of the following. The method further includes performing a tungsten-fill process to fill or partially fill the one or more features. The CVT process is a plasma process that reduces the tungsten oxide to tungsten. The CVT process includes exposing the tungsten-containing layer to an inductively coupled plasma (ICP) comprising hydrogen and oxygen. Exposing the tungsten-containing layer to an ICP is performed at a temperature of 400 degrees Celsius or less and includes supplying a processing gas comprising greater than or equal to 90% of hydrogen gas of a total flow of hydrogen gas and oxygen gas. The nucleation layer deposition cycle is performed in a process chamber without breaking vacuum. The at least one feature includes a bottom surface and at least one sidewall and has one or more conformal layers formed over the at least one sidewall and the bottom surface. The one or more conformal layers include a titanium nitride barrier layer, a tungsten liner layer, or tungsten liner layer formed on a titanium nitride barrier layer. The one or more reducing agents are selected from borane (BH3), diborane (B2H6), triethylborane, silane (SiH4), disilane (Si2H6), trisilane (Si3H8), tetrasilane (Si4H10), methylsilane (SiCH6), dimethylsilane (SiC2H), or a combination thereof. The one or more reducing agents include diborane and silane.

In another aspect, a method of filling a feature formed on a substrate is provided. The method includes forming a tungsten-containing nucleation layer in at least one feature formed on a substrate positioned in a processing region by performing a nucleation layer deposition cycle. The nucleation layer deposition cycle includes exposing the at least one feature of the substrate to one or more reducing agents in the processing region at a reducing agent flow rate, wherein the one or more reducing agents include silane, diborane, or a combination thereof, purging the processing region of the one or more reducing agents, exposing the at least one feature formed on the substrate to a tungsten-containing precursor gas in the processing region at a precursor flow rate, wherein the tungsten-containing precursor gas and the reducing agent form a portion of the nucleation layer within the at least one feature, purging the processing region of the tungsten-containing precursor gas, and exposing the portion of the nucleation layer to a chemical vapor transport (CVT) process to remove impurities from the portion of the nucleation layer. The CVT process is performed at a temperature of 400 degrees Celsius or less and includes forming a plasma from a processing gas comprising greater than or equal to 90% of hydrogen gas of a total flow of hydrogen gas and oxygen gas. The method further includes repeating the nucleation layer deposition cycle until the nucleation layer achieves a desired thickness. The method further includes exposing the at least one feature to the tungsten-containing precursor gas to form a tungsten fill layer over the tungsten-containing nucleation layer.

Implementations may include one or more of the following. The at least one feature is formed within a field region of a surface of the substrate and the at least one feature has a sidewall surface and a bottom surface, and the deposited tungsten-containing nucleation layer is formed over at least the sidewall surface, and the bottom surface of the at least one feature. The tungsten-containing precursor gas includes WF6. The CVT process includes an inductively coupled plasma or a capacitively coupled plasma. The inductively coupled plasma or the capacitively coupled plasma are formed from one or more of H2, O2, Ar, or a combination thereof. The CVT process includes exposing the tungsten-containing layers to a hydrogen and oxygen plasma treatment. The hydrogen and oxygen plasma treatment is performed at temperatures of 400 degrees Celsius or less and includes supplying a processing gas comprising greater than or equal to 90% of hydrogen gas of a total flow of hydrogen gas and oxygen gas. The sidewall surface is defined by a dielectric material selected from silicon oxide, silicon nitride, silicon oxynitride, or a combination thereof. The method further includes forming a tungsten liner layer over the at least one feature via a physical vapor deposition process and forming the tungsten-containing nucleation layer over the tungsten liner layer via an atomic layer deposition (ALD) process. Forming the tungsten fill layer over the tungsten-containing nucleation layer includes a chemical vapor deposition (CVD) gap-fill process.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a flow chart of a method for manufacturing a semiconductor device in accordance with one or more embodiments of the present disclosure.

FIGS. 2A-2F illustrate views of various stages of manufacturing a semiconductor device in accordance with one or more embodiments of the present disclosure.

FIG. 3 illustrates a flow chart of a method for forming a nucleation layer in accordance with one or more embodiments of the present disclosure.

FIG. 4 illustrates a schematic top view of one example of a multi-chamber processing tool in accordance with one or more embodiments of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

In the Summary above and in the Detailed Description, and the claims below, and in the accompanying drawings, reference is made to particular features (including method steps) of the present disclosure. It is to be understood that the disclosure in this specification includes all possible combinations of such particular features. For example, where a particular feature is disclosed in the context of a particular aspect or implementation of the present disclosure, or a particular claim, that feature can also be used, to the extent possible in combination with and/or in the context of other particular aspects and implementations of the present disclosure, and in the present disclosure generally.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

The term “at least” followed by a number is used herein to denote the start of a range beginning with that number (which may be a range having an upper limit or no upper limit, depending on the variable being defined). For example, “at least 1” means 1 or more than one. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. When, in this specification, a range is given as “(a first number) to (a second number)” or “(a first number)-(a second number),” this means a range whose lower limit is the first number and whose upper limit is the second number. For example, 25 to 100 mm means a range whose lower limit is 25 mm, and whose upper limit is 100 mm.

At earlier nodes, larger dimensions made tungsten (W) fill possible using nucleation followed by conformal CVD deposition. However, tungsten-fill is adversely affected by the presence of impurities. For example, the presence of boron impurities and/or fluorine-terminated (F-terminated) impurities on the surface of a tungsten liner or nucleation layer present in the feature adversely affect the resistivity of the deposited layers. Other impurities such as nitrogen, and tungsten oxide may also adversely affect tungsten-fill. One way to achieve good gap-fill is by coating contaminated tungsten surfaces with a nucleation layer (e.g., a boron-tungsten nucleation layer) to hide damage. However, the presence of boron in the nucleation layer may increase the resistivity penalty due to the high boron level in the nucleation layer.

Various embodiments provide improved tungsten gap-fill in features having reduced critical dimensions. In various embodiments, this may be achieved by performing a chemical vapor transport (CVT) process while forming a nucleation layer. This CVT process purifies or recovers the nucleation layer by reducing the presence of impurities such as boron, fluorine, and nitrogen, which may be present on the surfaces of the nucleation layer as it is formed.

Various embodiments utilize hydrogen and oxygen plasma treatment to recover the tungsten surface of the nucleation layer by, for example, reducing the boron level, which shows significant increase during deposition of the nucleation layer, via chemical vapor transportation. Through this method, the tungsten surface of the nucleation layer is purified, for example, by reducing or removing contaminants such as boron, nitrogen, and/or fluorine. The hydrogen and oxygen plasma treatment can include a saturation conformal treatment, which includes a longer soak time and/or high reactant treatment. In various embodiments, the hydrogen and oxygen plasma treatment can be performed at temperatures less than 400 degrees Celsius. In various embodiments, the hydrogen and oxygen plasma treatment includes H2% greater than or equal to 90% of the total flow of hydrogen and oxygen. During the plasma treatment process, the tungsten may be oxidized to form the volatile compound WO2(OH)2, which is immediately reduced back to tungsten. Through this mechanism, the surface of the nucleation layer is recovered and good subsequent gap-fill may be achieved without sacrificing resistance. Thus, in some embodiments, not only is good gap-fill achieved but impurities are also reduced because the tungsten surface is recovered by the CVT mechanism.

In some embodiments, the high H2% in H2+O2 co-flow plasma is used to purify each nucleation cycle, resulting in low impurities and a lower resistivity nucleation layer. As the tungsten-nucleation grows on top of TiN/PVD liners, the high resistivity nucleation layer is deposited during the impurities of the nucleation layer. In some embodiments, high H2% (>90%) in H₂+O₂ co-flow plasma treatments are performed right after each cycle of BW/SW/BSW nucleation. Through this approach, the resistivity of the tungsten film can substantially match the in-situ PVD+CVD no nucleation process, which has the lowest resistivity. In some embodiments, during the tungsten-gapfill process, the nucleation layer is deposited over or on top of TiN or PVD W liners before tungsten-bulk filling. However, as currently constituted, the nucleation layer is a high resistance film, thus, trying to thin it down is one possible approach, but thinning often results in step coverage degradation. In some embodiments, the resistivity of the nucleation layer is lowered by the high H₂% (>90%) in H₂+O₂ plasma-treatment after each deposition cycle of the cyclic nucleation layer deposition process. The stack resistivity of the nucleation layer described herein matches or substantially matches with the in-situ PVD+CVD process with no nucleation layer, which has the lowest resistivity. IN some embodiments, the saturated/conformal high H₂% (>=90%) in H₂+O₂ plasma treatment after each nucleation cycle can help to purify/reduce the impurities (especially for boron %) via chemical vapor transport (CVT).

At operation 110, a substrate is provided. The substrate may be a device substrate or a semiconductor substrate as described herein. The substrate may include multiple layers. The substrate has one or more features formed therein. The one or more features may include a sidewall surface and a bottom surface. The sidewall surface may be defined by a dielectric material and the bottom surface may be defined by a dielectric material or other materials, for example, a silicide layer, a metal silicide layer, a semiconductor layer, etch stop layers, or a metal layer.

At operation 120, one or more conformal layers may be formed over the surfaces of the one or more features. The one or more conformal layers can include one or more of barrier, adhesion, and/or liner layers. The one or more conformal layers can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, the like, or a combination thereof, or a carbide, for example, tungsten carbide, aluminum carbide, the like, or combination thereof. The one or more conformal layers may be formed by any suitable deposition process such as ALD, CVD, PVD, or a hybrid ALD/CVD process. The one or more conformal layers may create an overhang portion in the field region, which obstructs or blocks top openings of the one or more features.

At operation 130, a nucleation layer may be formed over the feature or the one or more conformal layers (if present). The nucleation layer may be used to repair any damage or discontinuities in the liner layer. The nucleation layer may be a boron-tungsten (BW) nucleation layer, a boron-silicon-tungsten (BSW) nucleation layer, a silicon-tungsten (BS) nucleation layer, or a tungsten-containing nucleation layer. The nucleation layer may be formed by a nucleation layer deposition cycle. Any suitable cyclic deposition process may be used to deposit the nucleation layer. The cyclic deposition process may be an atomic layer deposition (ALD) process, a cyclic chemical vapor deposition (CCVD) process, or a combination thereof (e.g., a hybrid ALD/CVD process). In addition to the cyclic deposition process, the nucleation layer deposition cycle further includes a chemical vapor transport (CVT) treatment process to remove impurities from the deposited portion of the nucleation layer. These impurities may include, for example, boron. In one example, one cycle of the cyclic deposition process includes a boron precursor pulse/a purge/a tungsten precursor pulse/a purge/CVT treatment. The cyclic deposition process may be repeated for any number of cycles sufficient to deposit a nucleation layer of targeted thickness. In one example, the cyclic deposition process is repeated for 3 to 5 cycles. The nucleation layer may also contribute to the thickness of the overhang portion (if present) formed by the one or more conformal layers during operation 120.

At operation 140, the one or more features may be filled with a metal-fill material, for example, a tungsten layer. The second tungsten layer may be a tungsten gap-fill layer. Any suitable tungsten deposition process may be used to deposit the tungsten gap-fill layer. The tungsten layer may be deposited via a chemical vapor deposition (CVD) gap-fill process. The tungsten layer may partially or completely fill the one or more features. The clean surfaces of the nucleation layer provide for good fill by the tungsten layer. In some embodiments, the feature may be partially filled with tungsten at operation 140 followed by additional treatment, for example, a nitrogen plasma treatment.

At operation 150, additional processing may be performed. In some embodiments, a planarization process, for example a CMP process or an etchback process may be performed to remove excess portions or overburden of the conductive material (if present). In some embodiments, an annealing process may be performed during operation 150.

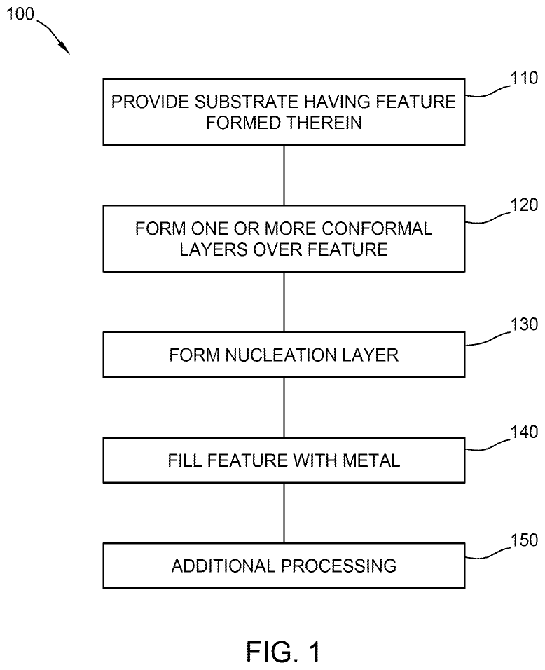

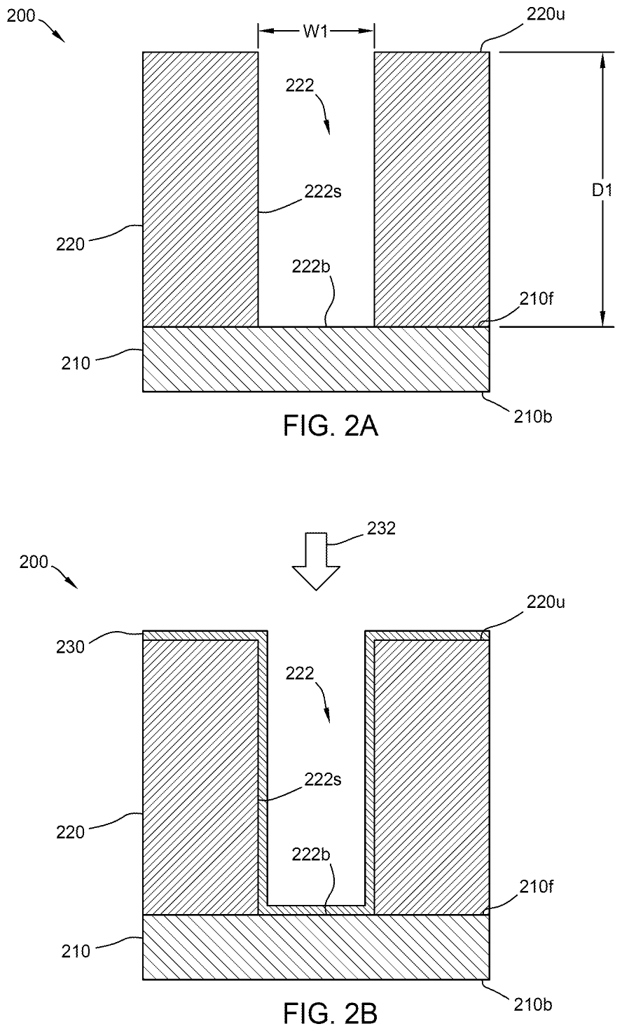

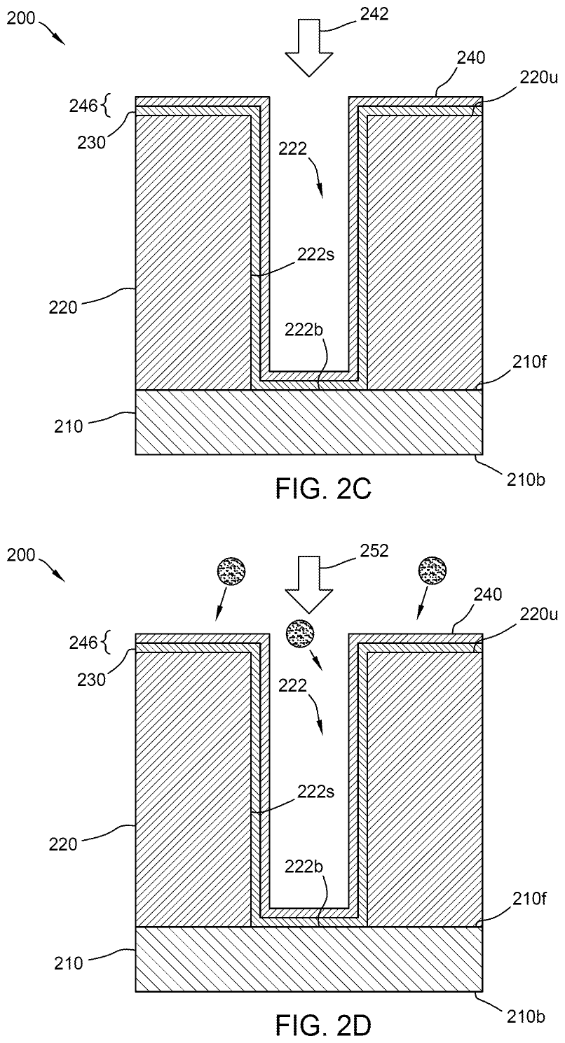

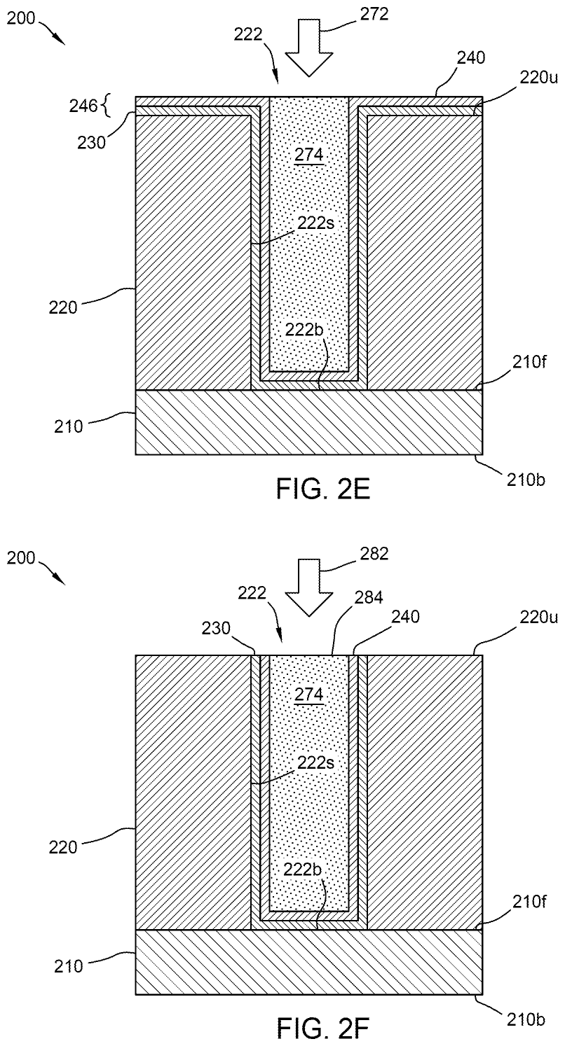

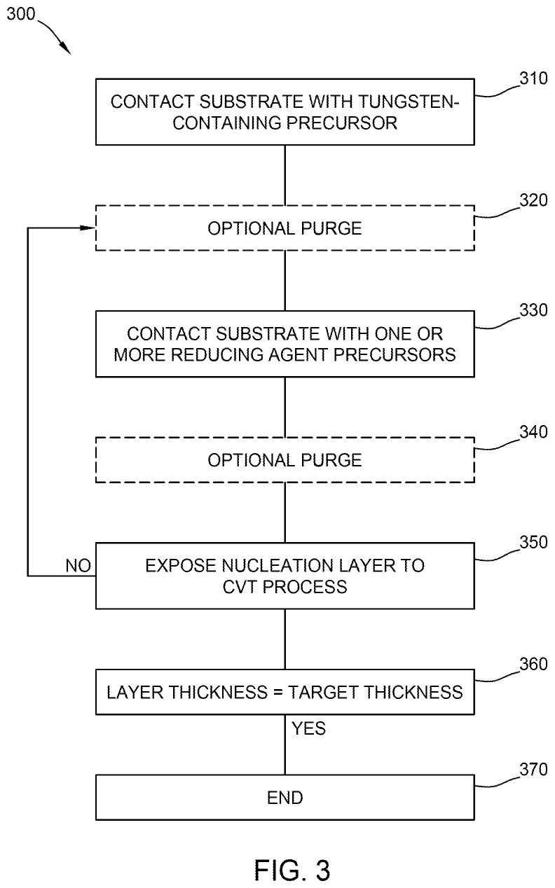

With reference to FIGS. 2A-2F, cross-sectional views of some embodiments of a device structure for semiconductor devices at various stages of manufacture are provided to illustrate the method of FIG. 1 and FIG. 3. Although FIGS. 2A-2F are described in relation to the method 100 and the method 300, it will be appreciated that the structure disclosed in FIGS. 2A-2F are not limited to the method 100 or the method 300, but instead may stand alone as structures independent of method 100 and method 300. Similarly, although the method 100 and the method 300 are described in relation to FIGS. 2A-2F, it will be appreciated that the method 100 and the method 300 are not limited to the structures disclosed in FIGS. 2A-2F, but instead may stand alone independent of the structures disclosed in FIGS. 2A-2F.

FIGS. 2A-2F illustrate views of various stages of manufacturing a semiconductor device in accordance with one or more embodiments of the present disclosure.

FIG. 2A illustrates a cross-sectional view of a semiconductor device structure 200 during intermediate stages of manufacturing corresponding to operation 110, in accordance with some embodiments. The semiconductor device structure 200 includes a device substrate 210 having one or more layers formed thereon, for example, a dielectric layer 220 as is shown in FIG. 2A. The device substrate 210 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the device substrate 210 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GalnAs, GaInP, and/or GaInAsP; a combination thereof, or the like. The device substrate 210 may include additional materials and/or layers, for example, silicide layers, metal silicide layers, metal layers, dielectric layers, etch stop layers, interlayer dielectrics, or a combination thereof.

The device substrate 210 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 210 to generate the structural and functional requirements of the design for the resulting semiconductor device structure 200.

The device substrate 210 has a frontside 210f (also referred to as a front surface) and a backside 210b (also referred to as a back surface) opposite the frontside 210f. The dielectric layer 220 is formed over the frontside 210f of the device substrate 210. The dielectric layer 220 may include multiple layers. The dielectric layer 220 includes an upper surface 220u or field region. In some embodiments, the dielectric layer 220 may include or be silicon oxide, silicon oxynitride, silicon nitride, a combination thereof, or multi-layers thereof. In some embodiments, the dielectric layer 220 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The dielectric layer 220 is patterned to form one or more feature(s) 222. In some embodiments, the feature 222 can be selected from a trench, a via, a hole, or combinations thereof. In particular embodiments the feature 222 is a via. In some embodiments, the feature 222 extends from the upper surface 220u of the dielectric layer 220 to the frontside 210f of the device substrate 210. The feature 222 includes sidewall surface 222s and a bottom surface 222b extending between the sidewall surface 222s. In some embodiments, the sidewall surface 222s are tapered. The sidewall surface 222s may be defined by the dielectric layer 220 and the bottom surface may be defined by the device substrate 210. In some embodiments, the sidewall surface 222s may be defined by the dielectric layer 220 and the bottom surface may also be defined by the dielectric layer 220. The feature 222 has a first depth “D1” from the upper surface 220u to the bottom surface 222b and a width “W1” between the two sidewall surface 222s. In some embodiments, the depth D1 is in a range of 2 nm to 200 nm, 3 nm to 200 nm, 5 nm to 100 nm, 2 nm to 100 nm, or 50 nm to 100 nm. In some embodiments, the width W1 is in a range of 10 nm to 100 nm, 10 nm to 20 nm, 10 nm to 50 nm, or 50 nm to 100 nm. In some embodiments, the feature 222 has an aspect ratio (D/W) in a range of 1 to 20, 5 to 10 to 20, or 15 to 20.

FIG. 2B illustrates a cross-sectional view of the semiconductor device structure 200 during intermediate stages of manufacturing corresponding to operation 120, in accordance with some embodiments. At operation 120, one or more conformal layers 230 may be formed over the surfaces of the feature. The one or more conformal layers 230 can include one or more barrier, adhesion, and/or liner layers. The one or more conformal layers 230 can include or be a nitride, for example, silicon nitride, carbon nitride, aluminum nitride, tantalum nitride, titanium nitride, tungsten nitride, the like, or a combination thereof, or a metal, for example, tantalum, cobalt, titanium, tungsten, the like, or a combination thereof, or a carbide, for example, tungsten carbide, aluminum carbide, the like, or combination thereof. The one or more conformal layers 230 may be formed by any suitable conformal layer deposition process 232 such as ALD, CVD, PVD, or a hybrid ALD/CVD process.

The one or more conformal layers 230 may be formed over the sidewall surface 222s and the bottom surface 222b of the feature 222 and on the upper surface 220u or field region of the dielectric layer 220. In some embodiments, the one or more conformal layers 230 include a barrier layer having a liner layer formed thereon, for example, a titanium nitride barrier layer having a tungsten liner formed thereon. In some embodiments, the one or more conformal layers 230 include a liner layer formed over the surfaces of the feature 222. The one or more conformal layers 230 may include or be a liner layer. The liner layer may be a tungsten liner layer. The liner layer may have an initial thickness in a range from about 1 Å to about 100 Å, for example, in a range from about 20 Å to about 50 Å. In some embodiments, the liner layer may be discontinuous along for example, the sidewall surface 222s and/or the bottom surface 222b. In particular embodiments, the liner layer is a tungsten liner layer, which is formed via a PVD process. The one or more conformal layers may create an overhang portion (not shown) along the upper surface 220u or the field region of the dielectric layer 220. The overhang portion may partially obstruct or block the top opening of the feature 222. The overhang portion may reduce the width W1 of the top opening.

FIGS. 2C and 2D illustrate a cross-sectional view of the semiconductor device structure 200 during intermediate stages of manufacturing corresponding to operation 130, in accordance with some embodiments. At operation 130, a nucleation layer, for example, a nucleation layer 240 is formed over the surfaces of the feature 222, for example, over the surface of the one or more conformal layers 230. The nucleation layer 240 may function as a seed layer for subsequent deposition of the metal-fill material. In addition, in some embodiments where the previously deposited one or more conformal layers 230 are discontinuous, for example, along the sidewall surface 222s, the nucleation layer 240 may repair discontinuous portions of the one or more conformal layers 230. The nucleation layer 240 may include or be any suitable material for facilitating the growth of the subsequently deposited metal-fill material. As will be discussed with FIG. 3, the nucleation layer 240 may be formed by any suitable cyclic nucleation layer deposition process 242 such as ALD, cyclic CVD (CCVD), or a hybrid ALD/CVD process. In addition to the cyclic deposition process, the nucleation layer deposition cycle further includes a chemical vapor transport (CVT) treatment process 252 as is shown in FIG. 2D to remove impurities from the deposited portion of the nucleation layer. These impurities may include, for example, boron.

In some embodiments, the nucleation layer 240 may include or be a tungsten-containing layer, for example, a boron-tungsten (BW) nucleation layer, a boron-silicon-tungsten (BSW) nucleation layer, a silicon-tungsten (BS) nucleation layer, or a tungsten-containing nucleation layer. The nucleation layer 240 may be a conformal layer. In some embodiments, the one or more conformal layers 230 include a barrier and/or liner layer having the nucleation layer formed thereon, for example, a tungsten liner layer having a boron-tungsten nucleation layer formed thereon. In some embodiments, the one or more conformal layers 230 and the nucleation layer 240 may be referred to individually or together as the tungsten-containing layers 246 as depicted in FIG. 2C.

In some embodiments, forming the nucleation layer 240 at operation 130 includes exposing the semiconductor device structure 200 to a tungsten-containing precursor gas at a first precursor gas flow rate followed by exposing the semiconductor device structure 200 to a reducing agent. The reducing agent may include boron and is introduced to the processing region at a reducing agent flow rate. The tungsten-containing precursor gas and the reducing agent may alternated cyclically to form the nucleation layer 240 over the semiconductor device structure 200 within the feature 222 at the reducing agent flow rate. The reducing agent and the tungsten-containing precursor gas may be cyclically alternated, beginning with either the reducing agent or the tungsten-containing precursor gas, and ending with the same beginning gas or ending with a gas different from the beginning gas. In some embodiments, the reducing agent or the tungsten-containing precursor gas are cyclically alternated beginning with the tungsten-containing precursor gas and ending in the reducing agent.

In some embodiments, the nucleation layer 240 is deposited using the ALD process. The ALD process includes repeating cycles of alternately exposing feature 222 to a tungsten-containing precursor and exposing the feature 222 to a reducing agent. In some embodiments, the processing region is purged between the alternating exposures. In some embodiments, the process region is continuously purged.

In some embodiments, exposing the substrate to the tungsten-containing precursor includes flowing the tungsten-containing precursor into the processing region from at a flow rate of about 100 sccm or less, such as in a range from about 10 sccm to about 60 sccm, or in a range from about 20 sccm to about 80 sccm. Exposing the semiconductor device structure 200 to the reducing agent includes flowing the reducing agent into the processing region at a flow rate of about 200 sccm to about 1000 sccm, such as between about 300 sccm and about 750 sccm. It should be noted that the flow rates for the various deposition and treatment processes described herein are for a processing system configured to process a 300 mm diameter substrate. Appropriate scaling may be used for processing systems configured to process different-sized substrates.

In some embodiments, the tungsten-containing precursor and the reducing agent are each flowed into the processing region for a duration in a range from about 0.1 seconds to about 10 seconds, such as in a range from about 0.5 seconds to about 5 seconds. The processing region may be purged between the alternating exposures by flowing a purge gas, such as argon (Ar) or hydrogen gas, into the processing region for a duration in a range from about 0.1 seconds to about 10 seconds, such as in a range from about 0.5 seconds to about 5 seconds.

Typically, the repeating cycles of the nucleation process continue until the nucleation layer 240 has a thickness in a range from about 10 Å to about 200 Å, such as in a range from about 10 Å to about 150 Å, or in a range from about 20 Å to about 150 Å. In one example, the ALD cycle is repeated for 3 to 5 cycles. The nucleation layer 240 is disposed along sidewall surface 222s and or the bottom surfaces 222b of the feature 222, such as over the one or more conformal layers 230. The nucleation layer 240 may also contribute to the thickness of any overhang portion formed by the liner layer during operation 120.

FIG. 2E illustrates a cross-sectional view of the semiconductor device structure 200 during intermediate stages of manufacturing corresponding to operation 140, in accordance with some embodiments. At operation 140, a metal-fill material, for example, a tungsten-fill material 274 is optionally deposited via a metal-fill process 272, at least partially, into the feature 222.

In some embodiments, the tungsten-fill material 274 is formed using a chemical vapor deposition (CVD) process comprising concurrently flowing (co-flowing) a tungsten-containing precursor gas, and a reducing agent into the processing region and exposing the semiconductor device structure 200 thereto. The tungsten-containing precursor and the reducing agent used for the tungsten-fill CVD process may include any combination of the tungsten-containing precursors and reducing agents described herein. In some embodiments, the tungsten-containing precursor includes WF₆, and the reducing agent includes hydrogen gas. In some embodiments, the tungsten-fill material 274 partially fills the features 222.

In some embodiments, the tungsten-containing precursor is flowed into the processing region at a flow rate in a range from about 10 sccm to about 1200 sccm, or more than about 50 sccm, or less than about 1000 sccm, or in a range from about 100 sccm to about 900 sccm. The reducing agent is flowed into the processing region at a rate of more than about 500 sccm, such as more than about 750 sccm, more than about 1000 sccm, or in a range from about 500 sccm and about 10000 sccm, such as in a range from about 1000 sccm to about 9000 sccm, or in a range from about 1000 sccm and about 8000 sccm.

In some embodiments, the tungsten-fill CVD process conditions are selected to provide a tungsten feature having a relativity low residual film stress when compared to conventional tungsten CVD processes. For example, in some embodiments, the tungsten-fill CVD process includes heating the substrate to a temperature of about 250° C. or more, such as about 300° C. or more, or in a range from about 250° C. to about 500° C., or in a range from about 300° C. to about 500° C. During the CVD process, the processing region may be maintained at a pressure of less than about 500 Torr, less than about 600 Torr, less than about 500 Torr, less than about 400 Torr, or in a range from about 1 Torr to about 500 Torr, such as in a range from about 1 Torr to about 450 Torr, or in a range from about 1 Torr to about 400 Torr, or for example, in a range from about 1 Torr and about 300 Torr.

In another embodiment, the tungsten-fill material 274 is deposited at operation 140 using an atomic layer deposition (ALD) process. The tungsten-fill ALD process includes repeating cycles of alternately exposing the semiconductor device structure 200 to a tungsten-containing precursor gas and a reducing agent and purging the processing region between the alternating exposures.

In some embodiments, the tungsten-containing precursor and the reducing agent are each flowed into the processing region for a duration of between about 0.1 seconds and about 10 seconds, such as between about 0.5 seconds and about 5 seconds. The processing region may be purged between the alternating exposures by flowing an inert purge gas, such as argon (Ar) or hydrogen, into the processing region for a duration in a range from about 0.1 seconds to about 10 seconds, such as in a range from about 0.5 seconds to about 5 seconds.

In other embodiments, the tungsten-fill material 274 is deposited using a pulsed CVD method that includes repeating cycles of alternately exposing the semiconductor device structure 200 to a tungsten-containing precursor gas and a reducing gas without purging the processing region. The processing conditions for the tungsten-fill pulsed CVD method may be the same, substantially the same, or within the same ranges as those described above for the tungsten-fill ALD process.

In some embodiments, the one or more conformal layers 230, the nucleation layer 240, and the tungsten-fill material 274 are monolithic and do not have an interface therebetween. The tungsten-fill material 274, the one or more conformal layers 230, and the nucleation layer 240 together may form a tungsten-containing layer.

FIG. 2F illustrates a cross-sectional view of the semiconductor device structure 200 during intermediate stages of manufacturing corresponding to operation 150, in accordance with some embodiments. At operation 150, the semiconductor device structure 200 may be exposed to additional processing 282. In some embodiments, the additional processing includes a planarization process, for example a chemical mechanical polishing (CMP) process or an etchback process may be performed to remove excess portions or overburden of the conductive material (if present) on the upper surface 220u of the dielectric layer 220. After completing the planarization process, a top surface 284 of the tungsten-fill material 274 may be co-planar or level with the upper surface 220u of the dielectric layer and the top surfaces of the nucleation layer 240 and the one or more conformal layers 230 as is shown in FIG. 2F. In some embodiments, an annealing process may be performed during operation 150.

A cyclic deposition process utilized for the formation of a nucleation layer, for example, the nucleation layer 240, may include exposing the substrate having the feature formed therein to a first vapor phase reactant, removing any unreacted first reactants and reaction byproducts from the processing region, and exposing the substrate to a second vapor phase reactant, followed by a second removal process. In some embodiments, the first vapor phase reactant may include a tungsten-containing precursor (e.g., WF6) and the second vapor phase reactant may include one or more reducing agent precursors. In other embodiments, the first vapor phase reactant may include one or more reducing agent precursors and the second vapor phase precursor may include the tungsten-containing precursor. The pulses of vapor phase reactants may be separated by an inert gas pulse, such as argon, helium, or other suitable inert gases to prevent gas phase reactions between reactants and enable self-saturating reactions.

One non-limiting example, of the cyclic deposition process includes ALD, where ALD is based on typically self-limiting reactions, whereby sequential and alternating pulses of reactants are used to deposit about one atomic (or molecular) monolayer of material per deposition cycle. The deposition conditions and precursors are typically selected to provide self-saturating reactions, such that an absorbed layer of one reactant leaves a surface termination that is non-reactive with the gas phase reactants of the same reactants. The substrate is subsequently contacted with a different reactant that reacts with the previous termination to enable continued deposition. Thus, each cycle of alternated pulses typically leaves no more than about one monolayer of the desired material. However, the skilled artisan will recognize that in one or more ALD cycles more than one monolayer of material may be deposited, for example, if some gas phase reactions occur despite the alternating nature of the process.

FIG. 3 illustrates a flow chart of a method 300 for forming a nucleation layer in accordance with one or more embodiments of the present disclosure. The method 300 can be implemented as the cyclic nucleation layer deposition process 242. The method 300 includes a cyclic deposition process (e.g., operations 310-340) to deposition a at least a portion of a nucleation layer, for example, a portion of the nucleation layer 240, followed by a CVT process (e.g., operation 350) to remove impurities from the at least a portion of the nucleation layer. The cyclic deposition process can be an ALD process, a cyclic chemical vapor deposition process, or a combination thereof (e.g., a hybrid ALD/CVD process). Precursors used during the cyclic deposition process may include tungsten-containing precursors, for example, tungsten hexafluoride (WF6), tungsten pentachloride (WCl5), and one or more reducing agent gases, for example, boron-containing precursors such as, for example, borane, diborane (B2H6), and silicon-containing precursor such as silane, disilane, and trisilane.

In some embodiments, during the cyclic nucleation layer deposition process 242, the processing region is maintained at a pressure of less than about 120 Torr, such as in a range from about 900 mTorr to about 120 Torr, in a range from about 1 Torr to about 100 Torr, or for example, in a range from about 1 Torr and about 50 Torr.

In some embodiments, prior to forming the nucleation layer 240, the substrate is exposed to a boron-containing gas, such as B₂H₆, such as for a soak time of about 5 seconds or greater, such as about 10 seconds or greater, such as about 20 seconds to 30 seconds. In some embodiments, prior to forming the nucleation layer 240, the substrate is exposed to a tungsten-containing gas, such as WF₆, such as for a soak time of about 5 seconds or greater, such as about 10 seconds or greater, such as about 20 seconds to 30 seconds. In some embodiments, prior to forming the nucleation layer 240, the substrate is exposed to the boron-containing gas for a soak time followed by the tungsten-containing gas for a soak time.

Turning to FIG. 3, at operation 310, a substrate, for example, the semiconductor device structure 200 having the feature 222 formed thereon is exposed to a tungsten-containing precursor at a first precursor gas flow rate. Examples of suitable tungsten-containing precursors include tungsten halides, such as tungsten hexafluoride (WF₆), tungsten hexachloride (WCl₆), tungsten pentachloride (WCl5), or a combination thereof. In some embodiments, the tungsten-containing precursor includes WF₆. In some embodiments, the tungsten-containing precursor includes an organometallic precursor and/or a fluorine-free precursor, for example, MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)₆), or a combination thereof.

In some embodiments, contacting the substrate, for example, the semiconductor device structure 200, with a first a vapor phase reactant including the tungsten-containing precursor may include contacting the tungsten-containing precursor to the substrate form a time period in a range from about 0.1 seconds to about 60 seconds, or in a range from about 0.1 seconds to about 10 seconds, or in a range from about 0.5 seconds to about 5.0 seconds. In addition, during the contacting of the substrate with the tungsten-containing precursor, the flow rate of the tungsten-containing precursor may be less than 1000 sccm, less than 500 sccm, or less than 100 sccm, or even less than 10 sccm. The flow rate of the tungsten-containing precursor may be at a flow rate of about 100 sccm or less, such as in a range from about 10 sccm to about 60 sccm, or in a range from about 20 sccm to about 80 sccm. It should be noted that the flow rates for the various deposition and treatment processes described herein are for a processing system configured to process a 300 mm diameter substrate. Appropriate scaling may be used for processing systems configured to process different-sized substrates.

At operation 320, a purge process may be optionally performed to remove any remaining tungsten chloride precursor and any byproducts from the processing region. For example, excess first vapor phase reactant and reaction byproducts (if any) may be removed from the surface of the substrate, for example, by pumping with inert gas. In some embodiments, the purge process may include a purge cycle wherein the processing region is purged for a time period of less than approximately 5 seconds, or less than approximately 3 seconds, or even less than approximately 2 seconds. Excess first vapor phase reactant, such as for example, excess tungsten-containing precursor and any possible reaction byproducts may be removed with the aid of a vacuum, generated by a pumping system in fluid communication with the processing region.

At operation 330, the substrate, for example, the semiconductor device structure 200 having the feature 222 formed thereon, is exposed to one or more reducing agent precursors at a second precursor gas flow rate. After purging the processing region, with a purge gas, the method 300 may continue with a second stage of the cyclic nucleation layer deposition process, which includes contacting the substrate with a second vapor phase reactant including one or more reducing agent precursors. The one or more reducing agent precursors react with the tungsten-containing precursor to deposit at least a portion of the nucleation layer 240.

In some embodiments, the reducing agent precursor may include at least one of a silicon-containing reducing agent, for example, silane (SiH4), disilane (Si2H6), trisilane (Si3H8), and a boron-containing precursor, for example, borane (BH3), or diborane (B2H6).

In some embodiments, contacting the substrate with the one or more reducing agent precursors may include contacting the substrate with the reducing agent precursor for a time period in a range from about 0.01 seconds to about 180 seconds, from about seconds to about 60 seconds, or in a range from about 0.1 seconds to about 10.0 seconds. In addition, during the contacting of the substrate with the one or more reducing agent precursors, the flow rate of the reducing agent precursor may be less than 30 slm, or less than 15 slm, or less than 10 slm, or less than 5 slm, or less than 1 slm, or even less than 0.1 slm. In addition, during the contacting of the substrate with the one or more reducing agent precursors to the substrate the flow rate of the reducing agent precursor may range from about 0.1 to 30 slm, from about 5 to 15 slm, or equal to or greater than slm. In some embodiments, exposing the semiconductor device structure 200 to the reducing agent includes flowing the one or more reducing agents into the processing region at a flow rate in a range from about 200 sccm to about 1000 sccm, or in a range from about 300 sccm to about 750 sccm.

At operation 340, a purge process may be optionally performed to remove any excess reducing agent precursors and reaction byproducts (if any) from the processing region. For example, excess second vapor phase reactant and reaction byproducts (if any) may be removed from the surface of the substrate, for example, by pumping with inert gas. In some embodiments, the purge process of operation 340 may include a purge cycle wherein the processing region is purged for a time period of less than approximately seconds, or less than approximately 3 seconds, or even less than approximately 2 seconds. Excess second vapor phase reactant, such as for example, excess reducing agent precursors and any possible reaction byproducts may be removed with the aid of a vacuum, generated by a pumping system in fluid communication with the processing region. For example, HCl or HF produced from the reaction of the one or more reducing agent precursors with excess chlorine or fluorine from the tungsten-containing precursor, may be removed from the processing region, e.g., by pumping while flowing an inert gas. In some embodiments, the purge process of operation 340 may include purging the substrate surface for a time period in a range from about 0.1 seconds to about 30 seconds, or from about 0.5 seconds to about 3 seconds, or even from about 1 second to about 2 seconds.

At operation 350, the nucleation layer or portion of the nucleation layer formed during operations 310-340, is exposed to a CVT process. The CVT process removes impurities from the deposited portion of the nucleation layer. For example, the CVT process may remove excess boron from the one or more reducing agent precursors and excess chlorine or fluorine remaining from the tungsten-containing precursor. The CVT process can recover or purify the surfaces of the nucleation layer 240 or deposited portion of the nucleation layer to achieve good gap-fill while maintaining or improving the resistivity of the formed device. In some embodiments, the CVT process includes a volatilization process and a reduction process. One example of the volatilization process may proceed via the following reaction (I):

WO2+2H2O→WO2(OH)2+H2 (I)

The reduction process may proceed via the following reaction:

WO2(OH)2+3H2→W+4H2O (II)

In some embodiments, the CVT process of operation 350 may include exposing the nucleation layer 240 or portion of the nucleation layer to a plasma treatment process. In some embodiments the plasma treatment process is an inductively coupled plasma process. In some embodiments, the plasma treatment process is a capacitively coupled plasma process. In some embodiments, the plasma treatment process is formed in a remote plasma source (RPS). In some embodiments, the plasma treatment process is generated within the processing region (e.g., a direct plasma). In some embodiments, the plasma treatment process includes exposing the nucleation layer to a plasma formed from a process gas including a hydrogen-containing gas and an oxygen-containing gas. In some embodiments, the plasma treatment process includes exposing the nucleation layer 240 to an ICP formed from a process gas including a hydrogen-containing gas and an oxygen-containing gas. The process gas may further include an inert gas, for example, argon (Ar), helium (He), krypton (Kr), or a combination thereof. In some embodiments, the plasma treatment process can include exposing the tungsten-containing layers 246 to a plasma formed form a process gas including one or more of H2, O2, Ar, or a combination thereof. In some embodiments, the plasma treatment process can include exposing the nucleation layer to a hydrogen and oxygen plasma treatment. The hydrogen and oxygen plasma treatment can include a saturation conformal treatment, which includes a longer soak time and/or high reactant treatment, to provide for good subsequent metal-fill of the feature.

In some embodiments, the plasma treatment process is performed at temperatures of 400 degrees Celsius or less. In some embodiments, the plasma treatment process includes supplying a processing gas including H2% greater than or equal to 90% of the total flow of hydrogen and oxygen.

In some embodiments, during the CVT process the processing region is maintained at a pressure of less than about 120 mTorr, such as in a range from about 50 mTorr to about 110 mTorr, in a range from about 60 mTorr to about 100 Torr, or for example, in a range from about 70 mTorr to about 90 mTorr. In some embodiments, the CVT region includes flowing hydrogen gas into the processing region or plasma source at a flow rate of about 300 sccm or less, such as in a range from about 100 sccm to about 250 sccm, or in a range from about 150 sccm to about 200 sccm. In some embodiments, the CVT process includes flowing oxygen gas into the processing region or plasma source at a flow rate of about 30 sccm or less, such as in a range from about 10 sccm to about sccm, or in a range from about 15 sccm to about 20 sccm. During the CVT process, a temperature of the semiconductor device structure 200 may be maintained in a range of about 400 degrees Celsius or less, such as in a range from about 200 degrees Celsius to about 400 degrees Celsius, or in a range from about 250 degrees Celsius to about 400 degrees Celsius, or for example, in a range from about 300 degrees Celsius to about 350 degrees Celsius. During the CVT process, plasma power of 2000 Watts or less, such as in a range from about 500 Watts to 1500 Watts, or for example, in a range from about 850 Watts to about 1000 Watts may be used. The CVT process may be performed for a time period of 60 seconds or less, such as in a range from about 10 seconds to about 40 seconds, or for example, in a range from about 15 seconds to about 30 seconds.

During the CVT, tungsten may be oxidized to form the volatile compound WO2(OH)2, which is immediately reduced back to tungsten. In addition, surface contaminants such as fluorine, nitrogen, and/or boron may be removed. Through these mechanisms, the surface of the tungsten is recovered and good subsequent metal-fill is achieved without sacrificing resistance. Thus, not only is good subsequent metal-fill achieved but impurities are also reduced because the tungsten surface is recovered by the CVT mechanism. This reduction in impurities decreases the resistivity of the formed nucleation layer, which decreases the overall resistivity of the formed device.

In other embodiments, the CVT includes a thermal treatment process. The thermal treatment process may include exposing the semiconductor device structure 200 to gases including H2 and H2O.

In some embodiments, operations 310-350 are performed in the same process chamber without breaking vacuum.

Operations 310-350 constitute one cyclic deposition cycle, which includes two deposition phases (operation 310 and operation 330) and optionally two purge phases (operation 320 and operation 340) followed by the CVT process (operation 350) to remove impurities. In some embodiments, each cycle is a self-limiting process, where less than or equal to about one tungsten containing monolayer is deposited during each cycle. Operations 310-350 may be repeated until a nucleation layer, such as the nucleation layer 240, reaches a desired (target) thickness. For example, at operation 360, if a thickness of the nucleation layer 240 equals a target thickness (or is within a given threshold of the target thickness), then the method 300 ends at operation 370. If the thickness of the nucleation layer 240 does not equal the target thickness (or is not within the given threshold of the target thickness), then the method 300 returns to operation 310 to begin another deposition cycle. In some embodiments, the cyclic deposition cycle (operation 310-350) are repeated until the nucleation layer 240 has a thickness of about 1 nm to about 20 nm. The cyclic deposition process may be repeated for any number of cycles sufficient to deposit a nucleation layer of targeted thickness. In one example, the cyclic deposition process is repeated for 3 to 5 cycles. Additional steps can be provided before, during, and after the cyclic deposition process, and some of the operation described can be moved, replaced, or eliminated for additional embodiments of the method 300.

It should also be appreciated that in some embodiments, the order of contacting the substrate with the first vapor phase reactant (e.g., the molybdenum chloride precursor or the tungsten chloride precursor) and the second vapor phase reactant (e.g., the reducing agent precursor) may be such that the substrate is first contacted with the second vapor phase reactant followed by the first vapor phase reactant. In addition, in some embodiments, the method 300 may include contacting the substrate with the first vapor phase reactant one or more times prior to contacting the substrate with the second vapor phase reactant one or more times. In addition, in some embodiments, the method 300 may include contacting the substrate with the second vapor phase reactant one or more times prior to contacting the substrate with the first vapor phase reactant one or more times.

In some embodiments the cyclic nucleation layer deposition process 242 may be a hybrid ALD/CVD or a CCVD process. In some embodiments, a cyclic chemical vapor deposition (CCVD) may include the introduction of two or more precursors into the reaction chamber wherein there may be a time period of overlap between the two or more precursors in the reaction chamber resulting in both an ALD component of the deposition and a CVD component of the deposition. For example, the CCVD process may include the continuous flow of one precursor and the periodic pulsing of a second precursor into the reaction chamber.

In one example, one cycle of the method 300 includes a WF6 dose or pulse/WF6 purge/a B2H6 dose or pulse/a B2H6 purge/H2+O2 plasma treatment.

In one example, one cycle of the ALD process includes a boron pulse/a boron purge/a tungsten pulse/a tungsten purge. The nucleation layer may also contribute to the thickness of the overhang portion (if present) formed by the one or more conformal layers during operation 120.

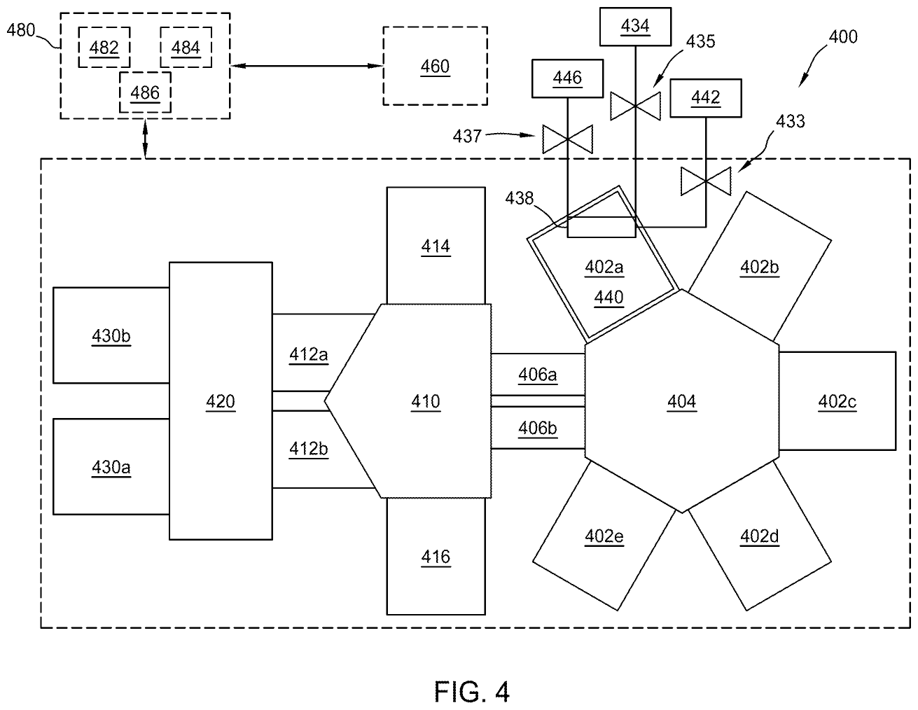

Examples of a processing system that may be suitably modified in accordance with the teachings provided herein include an integrated processing system or other suitable processing systems commercially available from Applied Materials, Inc., located in Santa Clara, California. It is contemplated that other processing systems (including those from other manufacturers) may be adapted to benefit from aspects described herein. FIG. 4 illustrates a schematic top-view diagram of an example of a multi-chamber processing system 400 or cluster tool that can be used to complete a gradient oxidation and etch of a PVD metal followed by a post-etch treatment process according to implementations of the present disclosure. As shown in FIG. 4, a plurality of process chambers 402a-e is coupled to a first transfer chamber 404. The first transfer chamber 404 is also coupled to a first pair of pass-through chambers 406a-b. The first transfer chamber 404 has a centrally disposed transfer robot (not shown) for transferring substrates between pass-through chambers 406a-b and the process chambers 402a-e. The pass-through chambers 406a-b are coupled to a second transfer chamber 410, which is coupled to a process chamber 414 that is configured to perform pre-clean process and a process chamber 416 that is configured to perform an epitaxial or alternatively, a PVD deposition process. The second transfer chamber 410 has a centrally disposed transfer robot (not shown) for transferring substrates between a set of load lock chamber 412a-b and the process chamber 414 or the process chamber 416. A factory interface 420 is connected to the second transfer chamber 410 by the load lock chambers 412. The factory interface 420 is coupled to one or more pods 430a-b on the opposite side of the load lock chambers 412. The pods 430a-b typically are front opening unified pods (FOUP) that are accessible from a clean room.

Prior to various operations, a substrate may first be transferred to the process chamber 414 where a pre-clean process is performed to remove contaminant, such as carbon or oxide contaminant from exposed surface of a source/drain region of a transistor of the substrate.

The substrate is then transferred to one or more of the process chambers 402. In some implementations, the process chamber 402 may etch a via or a trench in the substrate. In some implementations, the substrate is provided to an etch chamber, which is not a part of the processing system that contains the process chambers 414, 416 and the one or more process chambers 402, to perform the trench formation process. In other operations, the substrate is provided with trenches formed therein. Once the trench is formed in the dielectric material, the substrate is transferred to the process chamber 414 for cleaning.

Then the substrate is transferred to the process chamber 416 and/or at least one of the process chambers 402 where operations are performed. For example, the substrate is transferred to at least one of the process chambers 402 where a metal deposition operation is performed to form a seed layer. The metal can be deposited in any suitable chamber such as a PVD, atomic layer deposition (ALD), epitaxial (EPI) or other suitable chamber.

The substrate may be transferred to one of the process chambers 402 where a gradient oxidation operation may be performed. The gradient oxidation may be performed in an inductively coupled plasma (ICP) reactor or other suitable plasma process chamber. The gradient oxidation operation is configured to oxidize unwanted portions of the metal layer formed on the substrate.

The substrate may be transferred to one of the process chambers 402 where an etch operation is performed to selectively remove the oxidized portions of the deposited metal layer. For example, the etch operation may be performed in an etch chamber. Alternately, the etch operation may be performed in the ICP reactor in which the gradient oxidation was performed.

After the etch operation the substrate may be transferred to one of the process chambers 402 where a post-etch treatment process is performed to reduce tungsten oxide to tungsten and optionally remove contaminants from the tungsten surface. For example, the post-etch treatment process may be performed in the ICP reactor in which the gradient oxidation and etchback were performed. The post-etch treatment process may be a CVT process, for example, a hydrogen and oxygen treatment process as described herein.

After the post-etch treatment process a portion of the deposited metal layer (e.g., seed material) will remain along the sidewall surfaces and the bottom surfaces of the feature or trench. The substrate can then be transferred to one of the process chambers 402 or 416 where a gap-fill operation is performed. The gap-fill operation may be performed in a CVD, ALD or other suitable chamber. For example, process chamber 402 or 416 may deposit a metal such as tungsten or other suitable material for growth from the seed layer at the bottom of the trench or feature for forming a portion of a microelectronic device.

A system controller 480 is coupled to the processing system 400 for controlling the processing system 400 or components thereof. For example, the system controller 480 may control the operations of the processing system 400 using a direct control of the process chambers 402, 404, 406, 410, 412, 414, 416, 420, 430 of the processing system 400 or by controlling controllers associated with the process chambers 402, 404, 406, 410, 412, 414, 416, 420, 430, 460. In operation, the system controller 480 enables data collection and feedback from the respective chambers to coordinate performance of the processing system 400.

The system controller 480 generally includes a central processing unit (CPU) 482, memory 484, and support circuits 486. The CPU 482 may be one of any form of a general purpose processor that can be used in an industrial setting. The memory 484, non-transitory computer-readable medium, or machine-readable storage device, is accessible by the CPU 482 and may be one or more of memory such as random access memory (RAM), read only memory (ROM), floppy disk, hard disk, or any other form of digital storage, local or remote. The support circuits 486 are coupled to the CPU 482 and may comprise cache, clock circuits, input/output subsystems, power supplies, and the like. The various implementations disclosed in this disclosure may generally be implemented under the control of the CPU 482 by executing computer instruction code stored in the memory 484 (or in memory of a particular process chamber) as, e.g., a computer program product or software routine. That is, the computer program product is tangibly embodied on the memory 484 (or non-transitory computer-readable medium or machine-readable storage device). When the computer instruction code is executed by the CPU 482, the CPU 482 controls the chambers to perform operations in accordance with the various implementations.

The system controller 480 is configured to perform methods such as the method 100 stored in the memory 484.

In some embodiments, the first process chamber 402 includes an oxygen source 442 that is fluidly coupled to a processing region 440 of the first process chamber 402, wherein the oxygen source 442 is configured to deliver an oxygen-containing gas to the processing region 440. The first process chamber 402 may further include a first flow control valve 433 that is configured to control the flow of oxygen-containing gas provided from the oxygen source 442 to the processing region 440. In some embodiments, the first process chamber 402 further includes a hydrogen source 434 that is fluidly coupled to the processing region 440 of the first process chamber 402, wherein the hydrogen source 434 is configured to deliver a hydrogen-containing gas to the processing region 440. The first process chamber 402 may further include a second flow control valve 435 that is configured to control the flow of the hydrogen-containing gas provided from the hydrogen source 434 to the processing region 440. The first process chamber 402 may further include an etching gas source 446 that is fluidly coupled to the processing region 440 of the first process chamber 402, wherein the etching gas source 446 is configured to deliver an etching gas to the processing region 440. The first process chamber 402 may further include a third flow control valve 437 that is configured to control the flow of the etching gas provided from the etching gas source 446 to the processing region 440. The first process chamber 402 may further include an inductively coupled plasma source 438 that is configured to generate a plasma in the processing region 440, wherein the plasma comprises the hydrogen-containing gas and the oxygen-containing gas.

In some embodiments, the system controller 480 is configured to control the first flow control valve 433 so that an amount of oxygen-containing gas provided to a surface of a substrate, disposed in the processing region 440 of the first process chamber 402, to preferentially oxidize one or more tungsten-containing layers disposed on a field region and sidewalls of features formed in the substrate by generating the plasma in the processing region 440 of first process chamber 402; control the third flow control valve 437 so that an amount of etching gas provided to the surface of the substrate preferentially etches the preferentially oxidized portions of the one or more tungsten-containing layers disposed on the field region and sidewalls of features formed in the substrate to be performed in the first process chamber 402; and control the first flow control valve 433 and the second flow control valve 435 to deliver an amount of the oxygen-containing gas and the hydrogen-containing gas to the processing region 440 to expose the one or more tungsten-containing layers to the post-etch treatment process comprises exposing the tungsten-containing layers to a hydrogen and oxygen plasma treatment process by generating an inductive coupled plasma comprising the oxygen-containing gas and the hydrogen-containing gas.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

1. A method of filling a feature on a substrate, comprising:
forming a nucleation layer in at least one feature formed on a substrate by performing a nucleation layer deposition cycle, comprising:
exposing the at least one feature formed on a substrate to a tungsten-containing gas at a precursor flow rate;
exposing the at least one opening of the substrate to one or more reducing agents at a reducing agent flow rate, wherein the tungsten-containing gas and the reducing agent form a portion of the nucleation layer within the at least one feature; and
exposing the portion of the nucleation layer to a chemical vapor transport (CVT) process to remove impurities from the portion of the nucleation layer; and
repeating the nucleation layer deposition cycle until the nucleation layer achieves a desired thickness.

2. The method of claim 1, further comprising performing a tungsten-fill process to fill or partially fill the one or more features.

3. The method of claim 2, wherein the CVT process is a plasma process that reduces the tungsten oxide to tungsten.

4. The method of claim 2, wherein the CVT process comprises exposing the tungsten-containing layer to an inductively coupled plasma (ICP) comprising hydrogen and oxygen.

5. The method of claim 4, wherein exposing the tungsten-containing layer to an ICP is performed at a temperature of 400 degrees Celsius or less and comprises supplying a processing gas comprising greater than or equal to 90% of hydrogen gas of a total flow of hydrogen gas and oxygen gas.

6. The method of claim 5, wherein the nucleation layer deposition cycle is performed in a process chamber without breaking vacuum.

7. The method of claim 6, wherein the at least one feature comprises a bottom surface and at least one sidewall and has one or more conformal layers formed over the at least one sidewall and the bottom surface.

8. The method of claim 7, wherein the one or more conformal layers comprise a titanium nitride barrier layer, a tungsten liner layer, or tungsten liner layer formed on a titanium nitride barrier layer.

9. The method of claim 1, wherein the one or more reducing agents are selected from borane (BH3), diborane (B2H6), triethylborane, silane (SiH4), disilane (Si2H6), trisilane (Si3H8), tetrasilane (Si4H10), methylsilane (SiCH6), dimethylsilane (SiC2H), or a combination thereof.

10. The method of claim 1, wherein the one or more reducing agents comprise diborane and silane.

11. A method of filling a feature formed on a substrate, comprising:
forming a tungsten-containing nucleation layer in at least one feature formed on a substrate positioned in a processing region by performing a nucleation layer deposition cycle, comprising:
exposing the at least one feature of the substrate to one or more reducing agents in the processing region at a reducing agent flow rate, wherein the one or more reducing agents comprise silane, diborane, or a combination thereof;
purging the processing region of the one or more reducing agents;
exposing the at least one feature formed on the substrate to a tungsten-containing precursor gas in the processing region at a precursor flow rate, wherein the tungsten-containing precursor gas and the reducing agent form a portion of the nucleation layer within the at least one feature;
purging the processing region of the tungsten-containing precursor gas;
exposing the portion of the nucleation layer to a chemical vapor transport (CVT) process to remove impurities from the portion of the nucleation layer, wherein exposing the CVT process is performed at a temperature of 400 degrees Celsius or less and comprises forming a plasma from a processing gas comprising greater than or equal to 90% of hydrogen gas of a total flow of hydrogen gas and oxygen gas;
repeating the nucleation layer deposition cycle until the nucleation layer achieves a desired thickness; and
exposing the at least one feature to the tungsten-containing precursor gas to form a tungsten fill layer over the tungsten-containing nucleation layer.

12. The method of claim 11, wherein the at least one feature is formed within a field region of a surface of the substrate and the at least one feature has a sidewall surface and a bottom surface, and the deposited tungsten-containing nucleation layer is formed over at least the sidewall surface, and the bottom surface of the at least one feature.

13. The method of claim 11, wherein the tungsten-containing precursor gas comprises WF6.

14. The method of claim 11, wherein the CVT process comprises an inductively coupled plasma or a capacitively coupled plasma.

15. The method of claim 14, wherein the inductively coupled plasma or the capacitively coupled plasma are formed from one or more of H₂, O2, Ar, or a combination thereof.

16. The method of claim 11, wherein the CVT process comprises exposing the tungsten-containing layers to a hydrogen and oxygen plasma treatment.

17. The method of claim 16, wherein the hydrogen and oxygen plasma treatment is performed at temperatures of 400 degrees Celsius or less and comprises supplying a processing gas comprising greater than or equal to 90% of hydrogen gas of a total flow of hydrogen gas and oxygen gas.

18. The method of any of claim 13, wherein the sidewall surface is defined by a dielectric material selected from silicon oxide, silicon nitride, silicon oxynitride, or a combination thereof.

19. The method of claim 13, further comprising forming a tungsten liner layer over the at least one feature via a physical vapor deposition process and forming the tungsten-containing nucleation layer over the tungsten liner layer via an atomic layer deposition (ALD) process.

20. The method of claim 14, wherein forming the tungsten fill layer over the tungsten-containing nucleation layer comprises a chemical vapor deposition (CVD) gap-fill process.
